(19) United States
(12) Patent Application Publication
(10) Pub. No.: US 2015/0287818 A1
(43) Pub. Date: Oct. 8, 2015

(54) SEMICONDUCTOR STRUCTURE

(71) Applicants: INDUSTRIAL TECHNOLOGY RESEARCH INSTITUTE, Hsinchu (TW); ACREO SWEDISH ICT AB, Kista (SE)

(72) Inventors: Cheng-Tyng YEN, Kaohsiung City (TW); Mietek BAKOWSKI, Kista (SE); Chien-Chung HUNG, Hsinchu City (TW); Sergey RESHANOV, Kista (SE); Adolf SCHONER, Kista (SE); Chwan-Ying LEE, Hsinchu City (TW)

(73) Assignees: ACREO SWEDISH ICT AB, Kista (SE); INDUSTRIAL TECHNOLOGY RESEARCH INSTITUTE, Hsinchu (TW)

(21) Appl. No.: 14/502,621

(22) Filed: Sep. 30, 2014

(30) Foreign Application Priority Data
Apr. 3, 2014 (TW) 103112472

(51) Int. Cl. H01L 29/78; H01L 29/10

(52) U.S. Cl. CPC H01L 29/7804; H01L 29/1095

(57) ABSTRACT

A semiconductor structure comprising a substrate, a drift layer, at least a doping region, an epitaxial channel, a gate oxide layer, a gate metal and an isolation layer is provided. The drift layer is disposed on the substrate. The doping region comprises a p-well region, an n+ region and a p+ region, wherein the n+ region and a portion of p+ region are disposed in the p-well region which is adjacent to the n+ region. The epitaxial channel is disposed over the drift layer and covers at least a portion of the n+ region. The epitaxial channel is composed of at least two epitaxial layers whose conduction types or doping concentrations are not identical. The gate oxide layer is disposed on the epitaxial channel. The gate metal is disposed on the gate oxide layer. The isolation layer is disposed on the gate metal and the gate oxide layer.

This application claims the benefit of Taiwan application Serial No. 103112472, filed Apr. 3, 2014, the disclosure of which is incorporated by reference herein in its entirety.

### TECHNICAL FIELD

The disclosure relates in general to a semiconductor structure, and a silicon carbide (SiC) metal oxide semiconductor field effect (MOSFET) structure.

### BACKGROUND

Silicon carbide (SiC), having the characteristics of wide bandgap (3.26 eV), high breakdown field (3 MV/cm) and high thermal conductivity (4.9 W/cm-K), has been considered as material for power switching devices. Power devices made of silicon carbide can easily endure a breakdown voltage over 1000V. For the same rated blocking voltage, SiC power devices need only 1/10 of thickness of drift layer (a low doping epitaxial layer used to support voltage).

### SUMMARY

The disclosure is directed to a semiconductor structure capable of increasing channel mobility of SiC MOSFET, reducing on-resistance and increasing current density of element through the use of buried multi-layer epitaxial channel.

According to one embodiment, a semiconductor structure is provided. The semiconductor structure comprises a substrate, a drift layer, at least a doping region, an epitaxial channel, a gate oxide layer, a gate metal and an isolation layer is provided. The drift layer is disposed on the substrate. The substrate and the drift layer are n-type conduction. The doping region comprises a p-well region, an n+ region and a p+ region. The n+ region is disposed in the p-well region. The p+ region is adjacent to the n+ region. At least a portion of p+ region is disposed in the p-well region. The epitaxial channel is disposed over the drift layer and covers at least a portion of the n+ region. The epitaxial channel is composed of at least two epitaxial layers. Conduction types or doping concentrations of the epitaxial layers are not identical. The gate oxide layer is disposed on the epitaxial channel. The gate metal is disposed on the gate oxide layer. The isolation layer is disposed on the gate metal and the gate oxide layer.

The above and other aspects of the disclosure will become better understood with regard to the following detailed description of the exemplary but non-limiting embodiment (s). The following description is made with reference to the accompanying drawings.

### BRIEF DESCRIPTION OF THE DRAWINGS

FIG. 1 is a schematic diagram of a semiconductor structure according to an embodiment of the disclosure.

FIGS. 2A-2D are an embodiment of procedures of a manufacturing method of the semiconductor structure of FIG. 1.

FIG. 3A is an enlargement of an epitaxial channel of a semiconductor structure according to an embodiment of the disclosure.

FIG. 3B is an enlargement of an epitaxial channel of a semiconductor structure according to another embodiment of the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

A number of embodiments are disclosed below with accompanying drawings for elaborating the disclosure. It should be noted that the drawings are simplified so as to provide clear descriptions of the embodiments of the disclosure, and the scales used in the drawings are not based on the scales of actual products. However, the embodiments of the disclosure are for detailed descriptions only, not for limiting the scope of protection of the disclosure.

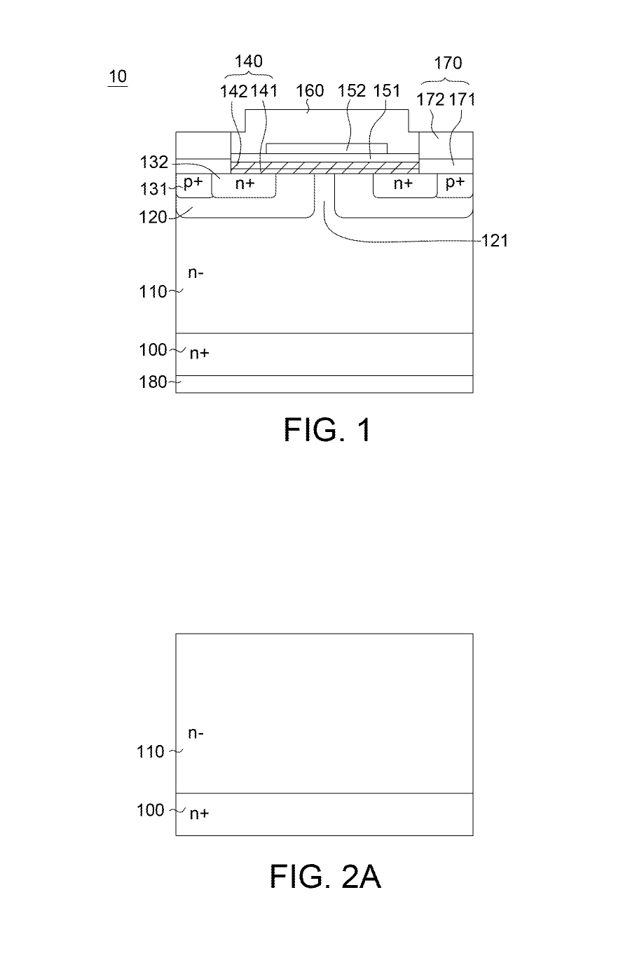

Referring to FIG. 1, a schematic diagram of a semiconductor structure according to an embodiment of the disclosure is shown. The semiconductor structure 10 is a vertical silicon carbide metal oxide semiconductor field effect (SiC MOSFET). In one of the exemplary embodiment, the semiconductor structure 10 can be repeatedly disposed to form a particular device, for example, a power device. The semiconductor structure 10 comprises a substrate 100, a drift layer 110, a p-well region 120, a p+ region 131, an n+ region 132, an epitaxial channel 140, a gate oxide layer 151, a gate metal 152, an isolation layer 160, a source conducting path 170 and a drain conducting layer 180. The drift layer 110 is disposed on the substrate 100. The p-well region 120, the p+ region 131 and the n+ region 132 (collectively “doping regions”) is formed in the drift layer 110. The semiconductor structure of FIG. 1 comprises two doping regions. The two doping regions are intervally disposed in the drift layer 110. That is, the semiconductor structure of FIG. 1 comprises two p-well regions 120, two p+ regions 131 and two n+ regions 132. The portion of the drift layer 110 between the two p-well regions 120 forms a junction field effect transistor (JFET) region 121. The n+ region 132 and at least a portion of the p+ region 131 are disposed in the p-well region 120, and the p+ region 131 and the n+ region 132 are adjacent to each other. The epitaxial channel 140 is a multi-layer epitaxial structure (exemplified by a bi-layer epitaxial structure in FIG. 1). The epitaxial channel at least covers a portion of the p-well region 120 and the n+ region 132. The gate oxide layer 151 is disposed on the epitaxial channel 140. The gate metal 152 is disposed on the gate oxide layer 151. The isolation layer 160 is disposed on the gate metal 152. A contact hole penetrates the isolation layer 160 and the epitaxial channel 140. A source conducting path 170 is electrically connected to the p+ region 131 and the n+ region 132, forming a good Ohmic contact. The drain conducting layer 180 is disposed on one side of the substrate 100 opposited to the drift layer 110 on the substrate (as illustrated in FIG. 1, the drain conducting layer 180 is disposed underneath the substrate 100). When the MOSFET is turned on, carriers (electrons) flow to the drain from the source, wherein the carriers pass through the source conducting path 170, the n+ region 132, the epitaxial channel 140, the junction field effect transistor (JFET) region 121, the drift layer 110, the substrate 100, and the drain conducting layer 180. Since current flows vertically between the drain on a bottom surface of MOSFET and the source on a top surface of MOSFET, this structure is referred as vertical MOSFET.

The semiconductor structure 10 is a power element. Let the n-type MOSFET of FIG. 1 be taken for example. In the present embodiment, the conduction type of the substrate 100 and the drift layer 110 is labeled as n type. However, in some embodiments, the semiconductor structure can also be realized by a p-type MOSFET (whose elements all have a conduction type opposite to that of an n-type MOSFET). The conduction type of the MOSFET is not restricted in the present disclosure.

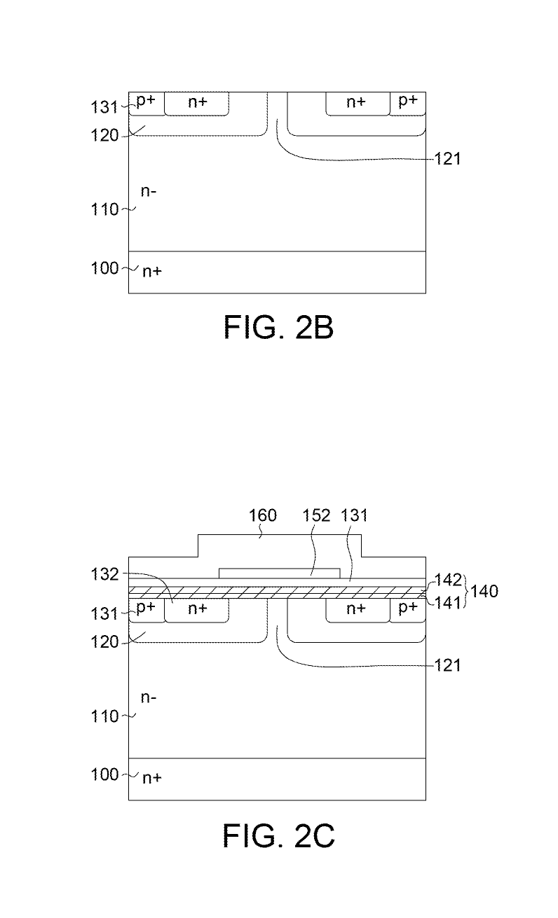

FIGS. 2A-2D are an embodiment of procedures of a manufacturing method of the semiconductor structure 10 of FIG. 1.

As indicated in FIG. 2A, a substrate 100 is provided, and a drift layer 110 is formed on the substrate 100. The substrate 100 can be made of different crystal orientations of SiC, such as 3C—SiC, 6H—SiC or 4H—SiC. The substrate 100 and the drift layer 110 both have n-type conduction. A doping concentration of the substrate 100 is higher than that of the drift layer 110. The substrate 100 and the drift layer 110 are represented by an n+ substrate and an n− drift layer respectively. In an embodiment, a doping concentration of the n+ substrate 100 is about 10¹⁸ to 10²¹ cm⁻³, and a doping concentration of the n− drift layer 110 is about 10¹⁴ to 10¹⁷ cm⁻³.

As indicated in FIG. 2B, a doping region is formed in the n− drift layer 110. The doping region comprises a p-well region 120, a p+ region 131 and an n+ region 132. The p+ region 131 and the n+ region 132 are adjacent to each other. Only a portion of the p+ region 131 is disposed in the p-well region 120, but the n+ region 132 is entirely disposed in the p-well region 120. A doping concentration of the p-well region 120 is higher than that of the n− drift layer 110, but a doping concentration of the p+ region 131 and the n+ region 132 are both higher than that of the p-well region 120. In FIG. 2B, two doping regions is intervally disposed in the drift layer 110, wherein the two doping regions have two p-well regions 120, two p+ regions 131 and two n+ regions 132. The portion of the n− drift layer 110 interposed between the two p-well regions 120 forms a junction field effect transistor (JFET) region 121.

As indicated in FIG. 2C, an epitaxial channel 140 is formed on the p-well region 120, the JFET region 121, the p+ region 131 and the n+ region 132. The epitaxial channel 140 is an epitaxial structure having more than two layers. Here, the epitaxial channel is exemplified by two layers, namely, the first epitaxial layer 141 and the second epitaxial layer 142. Afterwards, a gate oxide layer 151 is formed on the epitaxial channel 140. Following that, a gate metal 152 is formed on the gate oxide layer 151. The position of the gate metal 152 at least corresponds to a portion of the n+ region 132, a portion of the p-well region 120 (interposed between the n+ region 132 and the JFET region 121), and the JFET region 121. An isolation layer 160 is further formed on the gate metal 152 to separate the gate from the source. In an embodiment, the gate metal 152 can be n-type poly silicon doped with high concentration of phosphorus. In an embodiment, the gate metal 152 can be p-type poly silicon doped with high concentration of boron. In some embodiments, the gate metal 152 can also be a metal gate made of such as aluminum or nickel, and the material of the gate metal is not restricted in the present disclosure.

According to the semiconductor structure disclosed in the present embodiment, the p-well region 120, the p+ region 131 and the n+ region 132 are disposed underneath the epitaxial channel 140. The activation of dopants in the p-well region 120, the p+ region 131 and the n+ region 132 (collectively “doping regions”) can be completed during the formation of the epitaxial channel. According to a manufacturing process, the channel layer is formed first and then the p-well region 120, the p+ region 131 and the n+ region 132 are subsequently formed on the channel layer, and an additional activation process is required. In comparison to this manufacturing process, the manufacturing process of the present embodiment dispenses with the extra activation process which affects the surface roughness of the epitaxial channel 140 and is capable of maintaining electrical properties of the epitaxial channel 140.

As indicated in FIG. 2D, a contact hole is formed in the isolation layer 160 and the epitaxial channel 140, and a source conducting path 170 is formed inside the contact hole. That is, the source conducting path 170 penetrates the isolation layer 160 and the epitaxial channel 140. The source conducting path 170 is electrically connected to the p+ region 131 and the n+ region 132 to form good Ohmic contact. Also, a drain conducting layer 180 is formed on one side of the substrate 100 whose opposite side is connected to the drift layer 110. The drain conducting layer 180 forms a good Ohmic contact with the substrate 100. Now, the semiconductor structure 10 of FIG. 1 is completed. In an embodiment, the source conducting path 170 is composed of a source contact layer 171 and a source conducting layer 172. The source contact layer 171 is made of metal silicide, for example, the source contact layer 171 can be formed by following steps: depositing nickel (Ni) or depositing a multi-metal stack comprising nickel and titanium, and then annealing the deposition layer at a temperature equal or above 900° C. Thus, a nickel silicide as source contact layer 171 is formed on the SiC surface. The source contact layer 171 can form good Ohmic contact with the p+ region 131 and the n+ region 132 disposed underneath the source contact layer 171. Connecting metal such as titanium, titanium nitride, aluminum copper or aluminum silicon copper is further deposited on the source contact layer 171 to form the source conducting layer 172. The drain conducting layer 180 can be formed by following steps: depositing nickel (Ni) or depositing a multi-metal stack comprising nickel and titanium, and then annealing the deposition layer at a temperature equal or above 900° C. Thus, a nickel silicide as drain conducting layer 180 is formed on the SiC surface. The drain conducting layer 180 can form good Ohmic contact with the bottom surface of substrate 100. A multi-metal stack comprising titanium, nickel, and silver can be further deposited on the bottom surface and used as connecting metal of the drain electrode. However, the present disclosure does not restrict the materials of the contact region.

In the semiconductor structure as indicated in FIG. 2D, the epitaxial channel 140 only covers a portion of the n+ region 132 but not the p+ region 131. The epitaxial channel overs the p+ region 131 is removed during the formation of the source conducting path 170. In some embodiments, the epitaxial channel 140 can also cover a portion of the p+ region 131.

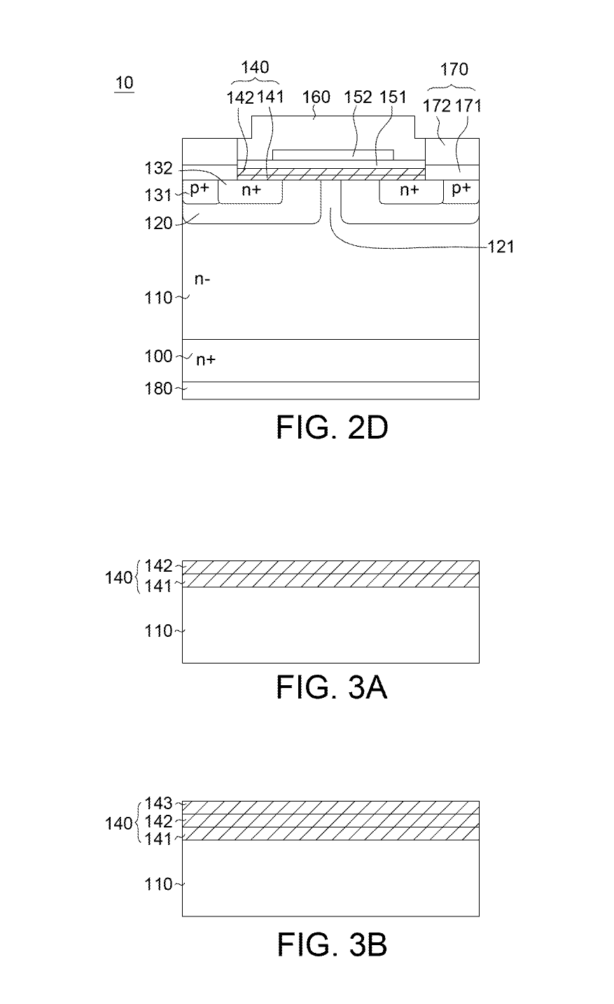

Refer to FIG. 3A and FIG. 3B. FIG. 3A is a schematic diagram of a bi-layer epitaxial channel. FIG. 3B is a schematic diagram of a tri-layer epitaxial channel (only detailed structure of the epitaxial channel 140 and the drift layer 110 are illustrated, and other elements are omitted). The epitaxial channel 140 comprises a first epitaxial layer 141, a second epitaxial layer 142 and a third epitaxial layer 143 in order. The second epitaxial layer 142 is disposed on the first epitaxial layer 141. The third epitaxial layer 143 is disposed on the second epitaxial layer 142. Doping concentration or conduction type of different epitaxial layers may be different. Doping concentration and concentration type can be changed by adjusting the flow and variety of the gas introduced during the growth of epitaxy. In an embodiment, an epitaxial layer having p-type conduction can be formed by introducing a gas containing aluminum, and an epitaxial layer having n-type conduction can be formed by introducing a gas containing nitrogen or phosphorus. Table 1 shows the influences of epitaxial channels on SiC MOSFET.

TABLE 1
Characteristics of SiC MOSFET

| | | | | | Electron |
|---|---|---|---|---|---|
| | Type of | Doping | | Threshold | mobility |
| | epitaxial | concentration | Thickness | voltage | μₘₐₓ |
| | channel | (cm⁻¹) | (nm) | Vₜₕ (V) | (cm²v⁻¹s⁻¹) |
| Comparison | none | 1.2*10¹⁸ | | 9.73 | 1.53 |
| example 1 | | | | | |
| Embodiment 1 | Bi-layer | 141: 1*10¹⁶ | L1: <100 | 3.29 | 10.77 |
| | nn | 142: 3*10¹⁵ | L2: <50 | | |
| Embodiment 2 | Bi-layer | 141: 1*10¹⁷ | L1: <100 | 2.42 | 13.88 |
| | nn | 142: 3*10¹⁵ | L2: <50 | | |
| Embodiment 3 | Tri-layer | 141: 8*10¹⁵ | L1: <100 | 1.96 | 14.33 |
| | pnp | 142: 1*10¹⁶ | L2: <50 | | |
| | | 143: 8*10¹⁵ | L3: <50 | | |
| Embodiment 4 | Tri-layer | 141: 8*10¹⁵ | L1: <100 | 1.34 | 17.05 |
| | pnp | 142: 1.2*10¹⁷ | L2: <50 | | |
| | | 143: 8*10¹⁵ | L3: <50 | | |

Table 1 shows measurement results of electrical properties of SiC MOSFET with one control experiment and four different epitaxial channels. However, these results are for explanatory purpose, not for limiting the scope of protection of the present disclosure. As indicated in Table 1, the MOSFET with a bi-layer epitaxial channel (embodiments 1 and 2) has an electron mobility 9 times higher than that of the MOSFET without epitaxial channel (comparison example 1), and the MOSFET with a tri-layer epitaxial channel (embodiments 3 and 4) has an electron mobility 1.6 times higher than that of the MOSFET with a bi-layer epitaxial channel. Therefore, the multi-layer epitaxial channel of the present disclosure is capable of effectively increasing electron mobility of elements. It should be noted that although bi-layer and tri-layer epitaxial structures are exemplified in above embodiments, the epitaxial structure can have more than four layers in actual application and the number of layers is not restricted thereto. In an embodiment, each epitaxial layer has a thickness between 1-500 nanometers (nm), and the multi-layer epitaxial channel has a thickness between 2-1000 nm.

Besides, the doping concentration and conduction type of each epitaxial layer also affect element characteristics. Let a bi-layer epitaxial layer (FIG. 3A) be taken for example. The conduction types of the first epitaxial layer 141 and the second epitaxial layer 142 may include three combination, namely, np, pn and nn. The doping concentrations and conduction types of the first epitaxial layer 141 and the second epitaxial layer 142 may not be the same. For example, when the conduction types of the epitaxial layers are np or pn, the doping concentration of the n-type epitaxial layer is higher than that of the p-type epitaxial layer. Let a tri-layer epitaxial layer (FIG. 3B) be taken for example. The conduction types of the first epitaxial layer 141, the second epitaxial layer 142 and the third epitaxial layer 143 may be pnp or nnn in order, and the n-type second epitaxial layer 142 interposed between the first epitaxial layer 141 and the third epitaxial layer 143 has the highest doping concentration. In an embodiment, each epitaxial layer has a doping concentration between 10¹⁴-10¹⁹ cm⁻³.

According to the semiconductor structure disclosed in above embodiments, an epitaxial channel with two or more than two layers is formed over the n+ region, the p+ region, the p-well region and JFET region of an SiC MOSFET, and through the adjustment in the doping concentration, conduction type and thickness of the multi-layer epitaxial channel structure, the impact on the channel by the SiC—SiO₂ interface defects is reduced, the concentration of the carriers in the channel is increased, and suitable threshold voltage is achieved. Meanwhile, such design makes the doping region activated during the formation of the epitaxial layers, avoids the epitaxial channel being damaged in an extra annealing step, and reduces the impact of roughness scattering. Accordingly, channel mobility is increased, on-resistance is reduced, and current density of element is increased.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a substrate;
a drift layer disposed on the substrate, wherein the substrate and the drift layer is n-type conduction;
a plurality of doping regions intervally disposed in the drift layer and a plurality of junction field effect transistor (JFET) regions formed between the doping regions, wherein each of the doping regions comprises:
a p-well region;
an n+ region disposed in the p-well region;
a p+ region adjacent to the n+ region, wherein at least a portion of the p+ region is disposed in the p-well region;
an epitaxial channel disposed over the drift layer and covering at least a portion of the n+ region, wherein the epitaxial channel is composed of at least two epitaxial layers, and the conduction types or doping concentrations of the epitaxial layers are not identical;
a gate oxide layer disposed on the epitaxial channel;
a gate metal disposed on the gate oxide layer; and
an isolation layer disposed on the gate metal and the gate oxide layer.

2. The semiconductor structure according to claim 1, wherein the epitaxial channel comprises a first epitaxial layer and a second epitaxial layer disposed on the first epitaxial layer, and at least one of the first epitaxial layer and the second epitaxial layer is n-type conduction.

3. The semiconductor structure according to claim 2, wherein the first epitaxial layer is n-type conduction, the second epitaxial layer is p-type conduction, and a doping concentration of the first epitaxial layer is higher than or equal to a doping concentration of the second epitaxial layer.

4. The semiconductor structure according to claim 2, further comprising a third epitaxial layer disposed on the second epitaxial layer, and at least one of the first epitaxial layer, the second epitaxial layer and the third epitaxial layer is n-type conduction.

5. The semiconductor structure according to claim 4, wherein the second epitaxial layer is n-type conduction, the doping concentration of the second epitaxial layer is higher than doping concentrations of the first epitaxial layer and the third epitaxial layer.

6. The semiconductor structure according to claim 1, further comprising:
a drain conducting layer disposed on one side of the substrate opposed to the drift layer on the substrate, wherein the drain conducting layer forms Ohmic contact with the substrate; and
a source conducting path penetrating the isolation layer and the epitaxial channel, wherein the source conducting path is electrically connected to the p+ region and the n+ region.

7. The semiconductor structure according to claim 6, wherein the source conducting path comprises a source conducting layer and a source contact layer, the source contact layer forms Ohmic contact with the p+ region and the n+ region, and the source contact layer is electrically connected to the source conducting layer.

8. The semiconductor structure according to claim 7, wherein the substrate is made of silicon carbide (SiC), the source conducting layer is made of metal, and the source contact layer is made of metal silicide.

9. The semiconductor structure according to claim 1, wherein the epitaxial layers have a thickness between 1-500 nm, and epitaxial channel has a thickness between 2-1000 nm.

10. The semiconductor structure according to claim 1, wherein the epitaxial layers have a doping concentration between 10¹⁴-10¹⁹ cm⁻³.

11. The semiconductor structure according to claim 1, wherein the activation of dopants in the doping regions is completed during the formation of the epitaxial channel.
